(19) United States
(12) Patent Application Publication
(10) Pub. No.: US 2023/0420367 A1
(43) Pub. Date: Dec. 28, 2023

(54) CONTACTS FOR STACKED FIELD EFFECT TRANSISTOR

(71) Applicant: INTERNATIONAL BUSINESS MACHINES CORPORATION, ARMONK, NY (US)

(72) Inventors: Ruilong Xie, Niskayuna, NY (US); Kisik Choi, Watervliet, NY (US); Su Chen Fan, Cohoes, NY (US); Albert M. Young, Fishkill, NY (US)

(21) Appl. No.: 17/808,568

(22) Filed: Jun. 24, 2022

(51) Int. Cl. H01L 23/528; H01L 21/822; H01L 21/768; H01L 23/48; H01L 25/065; H01L 27/092

(52) U.S. Cl. CPC H01L 23/5286; H01L 21/8221; H01L 21/76898; H01L 21/76897; H01L 23/481; H01L 25/0657; H01L 27/092; H01L 2225/06541

(57) ABSTRACT

A semiconductor device is provided. The semiconductor device includes a first field effect transistor (FET); a second FET stacked over the bottom FET; a backside contact (BSCA) connected to a backside power rail (BSPR); and a via to backside power rail (VBPR), the VBPR landing over the BSCA.

### BACKGROUND

The present disclosure relates to fabrication methods and resulting structures for semiconductor devices. More specifically, the present disclosure relates to fabrication methods and resulting structures for field effect transistors (FETs) with stacked n-type and p-type nanosheets for complementary metal oxide semiconductor (CMOS) technologies.

In certain semiconductor device fabrication processes, a large number of semiconductor devices, such as n-type field effect transistors (nFETs) and p-type field effect transistors (pFETs), may be fabricated on a single wafer. Non-planar transistor device architectures (e.g., fin-type FETs (FinFETs) and nanosheet FETs) can provide increased device density and increased performance over planar transistors. To further increase the transistor density, one approach is to stack one device over another to double the active density at a given footprint. The stacked FET can have various different configurations, e.g., one nanosheet device over another nanosheet device, one FINFET device over another FINFET device, one FINFET device over one nanosheet device, one nanosheet device over one FINFET device, one planar device over one FINFET device, one planar device over another nanosheet device, etc.

### SUMMARY

Embodiments of the present disclosure relate to a semiconductor device. A semiconductor device is provided. The semiconductor device includes a first field effect transistor (FET); a second FET stacked over the bottom FET; a backside contact (BSCA) connected to a backside power rail (BSPR); and a via to backside power rail (VBPR), the VBPR landing over the BSCA.

Embodiments of the present disclosure relate to a method of manufacturing a semiconductor device. The method includes forming a first field effect transistor (FET); forming a second FET that is stacked over the bottom FET; forming a backside contact (BSCA) that is connected to a backside power rail (BSPR); and forming a via to backside power rail (VBPR), the VBPR landing over the BSCA.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1A is a cross-sectional view of a semiconductor device at an intermediate stage of the fabrication process and taken along the X1 line of FIG. 1D, according to embodiments.

FIG. 1B is a cross-sectional view of the semiconductor device of FIG. 1A taken along the X2 line of FIG. 1D, according to embodiments.

FIG. 1C is a cross-sectional view of the semiconductor device of FIG. 1A taken along the Y line of FIG. 1D, according to embodiments.

FIG. 1D is a top view of the semiconductor device of FIG. 1A, according to embodiments.

FIG. 2A is a cross-sectional view of the semiconductor device of FIG. 1A after additional fabrication operations and taken along the X1 line of FIG. 2D, according to embodiments.

FIG. 2B is a cross-sectional view of the semiconductor device of FIG. 1B after additional fabrication operations and taken along the X2 line of FIG. 2D, according to embodiments.

FIG. 2C is a cross-sectional view of the semiconductor device of FIG. 1C after additional fabrication operations and taken along the Y line of FIG. 2D, according to embodiments.

FIG. 2D is a top view of the semiconductor device of FIG. 2A-2C, according to embodiments.

FIG. 3A is a cross-sectional view of the semiconductor device of FIG. 2A after additional fabrication operations and taken along the X1 line of FIG. 2D, according to embodiments.

FIG. 3B is a cross-sectional view of the semiconductor device of FIG. 2B after additional fabrication operations and taken along the X2 line of FIG. 2D, according to embodiments.

FIG. 3C is a cross-sectional view of the semiconductor device of FIG. 2C after additional fabrication operations and taken along the Y line of FIG. 2D, according to embodiments.

FIG. 4A is a cross-sectional view of the semiconductor device of FIG. 3A after embodiments.

FIG. 4B is a cross-sectional view of the semiconductor device of FIG. 3B after additional fabrication operations and taken along the X2 line of FIG. 2D, according to embodiments.

FIG. 4C is a cross-sectional view of the semiconductor device of FIG. 3C after additional fabrication operations and taken along the Y line of FIG. 2D, according to embodiments.

FIG. 5A is a cross-sectional view of the semiconductor device of FIG. 4A after additional fabrication operations and taken along the X1 line of FIG. 2D, according to embodiments.

FIG. 5B is a cross-sectional view of the semiconductor device of FIG. 4B after additional fabrication operations and taken along the X2 line of FIG. 2D, according to embodiments.

FIG. 5C is a cross-sectional view of the semiconductor device of FIG. 4C after additional fabrication operations and taken along the Y line of FIG. 2D, according to embodiments.

FIG. 6A is a cross-sectional view of the semiconductor device of FIG. 5A after additional fabrication operations and taken along the X1 line of FIG. 2D, according to embodiments.

FIG. 6B is a cross-sectional view of the semiconductor device of FIG. 5B after additional fabrication operations and taken along the X2 line of FIG. 2D, according to embodiments.

FIG. 6C is a cross-sectional view of the semiconductor device of FIG. 5C after additional fabrication operations and taken along the Y line of FIG. 2D, according to embodiments.

FIG. 7A is a cross-sectional view of the semiconductor device of FIG. 6A after embodiments.

FIG. 7B is a cross-sectional view of the semiconductor device of FIG. 6B after additional fabrication operations and taken along the X2 line of FIG. 2D, according to embodiments.

FIG. 7C is a cross-sectional view of the semiconductor device of FIG. 6C after additional fabrication operations and taken along the Y line of FIG. 2D, according to embodiments.

FIG. 8A is a cross-sectional view of the semiconductor device of FIG. 7A after additional fabrication operations and taken along the X1 line of FIG. 2D, according to embodiments.

FIG. 8B is a cross-sectional view of the semiconductor device of FIG. 7B after additional fabrication operations and taken along the X2 line of FIG. 2D, according to embodiments.

FIG. 8C is a cross-sectional view of the semiconductor device of FIG. 7C after additional fabrication operations and taken along the Y line of FIG. 2D, according to embodiments.

FIG. 9A is a cross-sectional view of the semiconductor device of FIG. 8A after additional fabrication operations and taken along the X1 line of FIG. 2D, according to embodiments.

FIG. 9B is a cross-sectional view of the semiconductor device of FIG. 8B after additional fabrication operations and taken along the X2 line of FIG. 2D, according to embodiments.

FIG. 9C is a cross-sectional view of the semiconductor device of FIG. 8C after additional fabrication operations and taken along the Y line of FIG. 2D, according to embodiments.

FIG. 10A is a cross-sectional view of the semiconductor device of FIG. 9A after embodiments.

FIG. 10B is a cross-sectional view of the semiconductor device of FIG. 9B after additional fabrication operations and taken along the X2 line of FIG. 2D, according to embodiments.

FIG. 10C is a cross-sectional view of the semiconductor device of FIG. 9C after additional fabrication operations and taken along the Y line of FIG. 2D, according to embodiments.

FIG. 11A is a cross-sectional view of the semiconductor device of FIG. 10A after additional fabrication operations and taken along the X1 line of FIG. 2D, according to embodiments.

FIG. 11B is a cross-sectional view of the semiconductor device of FIG. 10B after additional fabrication operations and taken along the X2 line of FIG. 2D, according to embodiments.

FIG. 11C is a cross-sectional view of the semiconductor device of FIG. 10C after additional fabrication operations and taken along the Y line of FIG. 2D, according to embodiments.

FIG. 12A is a cross-sectional view of the semiconductor device of FIG. 11A after additional fabrication operations and taken along the X1 line of FIG. 2D, according to embodiments.

FIG. 12B is a cross-sectional view of the semiconductor device of FIG. 11B after additional fabrication operations and taken along the X2 line of FIG. 2D, according to embodiments.

FIG. 12C is a cross-sectional view of the semiconductor device of FIG. 11C after additional fabrication operations and taken along the Y line of FIG. 2D, according to embodiments.

### DETAILED DESCRIPTION

The present disclosure describes stacked FET devices and methods of manufacturing the stacked FET devices. In particular, the present disclosure describes the particular contact wiring structures formed therein. In certain examples, forming contacts for stacked FET devices may have certain challenges regarding layout and the potential for electrical shorting. Therefore, it may be desirable to manufacture stacked FET structures with improved routing characteristics for the backside power rail (BPR) and the backside power distribution network (BSPDN).

The flowcharts and cross-sectional diagrams in the Figures illustrate methods of manufacturing stacked FET devices according to various embodiments. In some alternative implementations, the manufacturing steps may occur in a different order that that which is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of an FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a so-called gate-all-around (GAA) nanosheet FET is a known architecture for providing a relatively small FET footprint by forming the channel region as a series of nanosheets. In a known GAA configuration, a nanosheet-based FET includes a source region, a drain region and stacked nanosheet channels between the source and drain regions. Semiconductor nanosheet FET devices typically include one or more suspended nanosheets that serve as the channel. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized. For n-type FETs, the channel nanosheets are typically silicon (Si) and the sacrificial nanosheets are typically silicon germanium (SiGe). For p-type FETs, the channel nanosheets can be SiGe and the sacrificial nanosheets can be Si. In some implementations, the channel nanosheet of a p-type FET can be SiGe or Si, and the sacrificial nanosheets can be Si or SiGe. Forming the GAA nanosheets from alternating layers of channel nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides superior channel electrostatics control, which is necessary for continuously scaling gate lengths down to seven (7) nanometer CMOS technology and below.

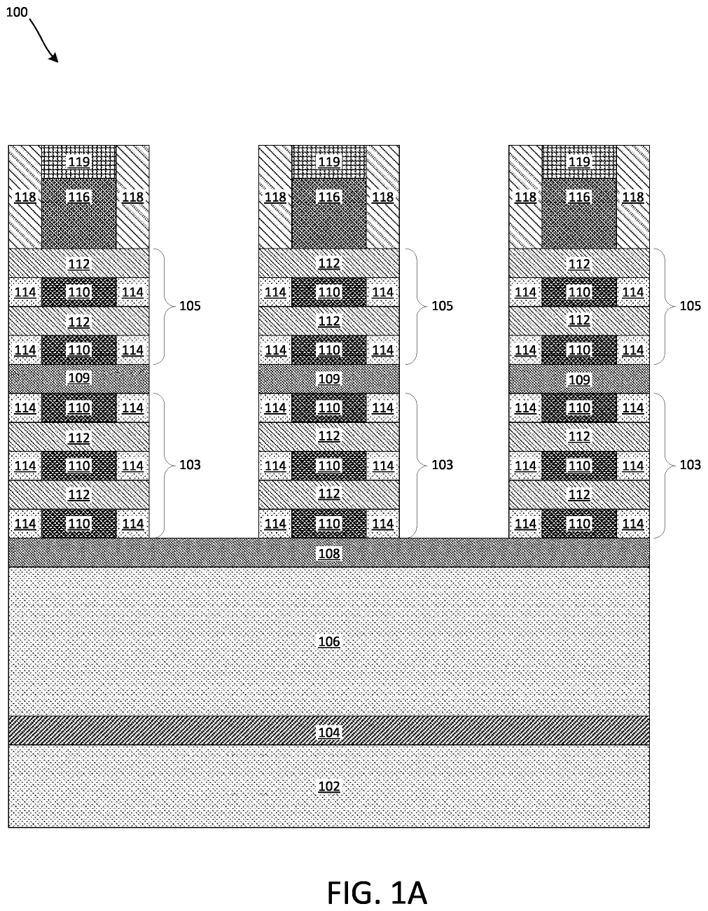

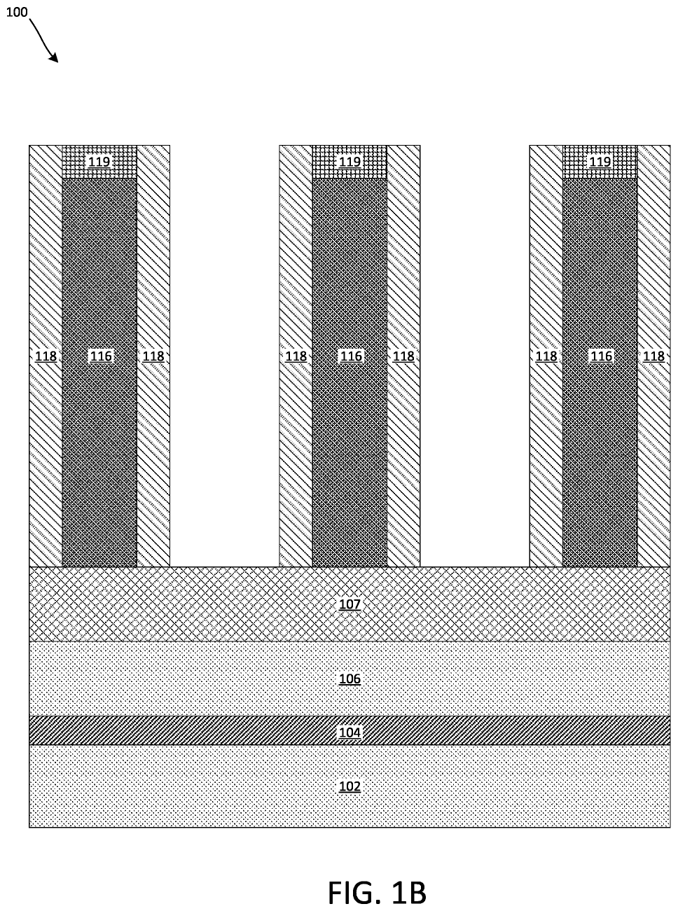

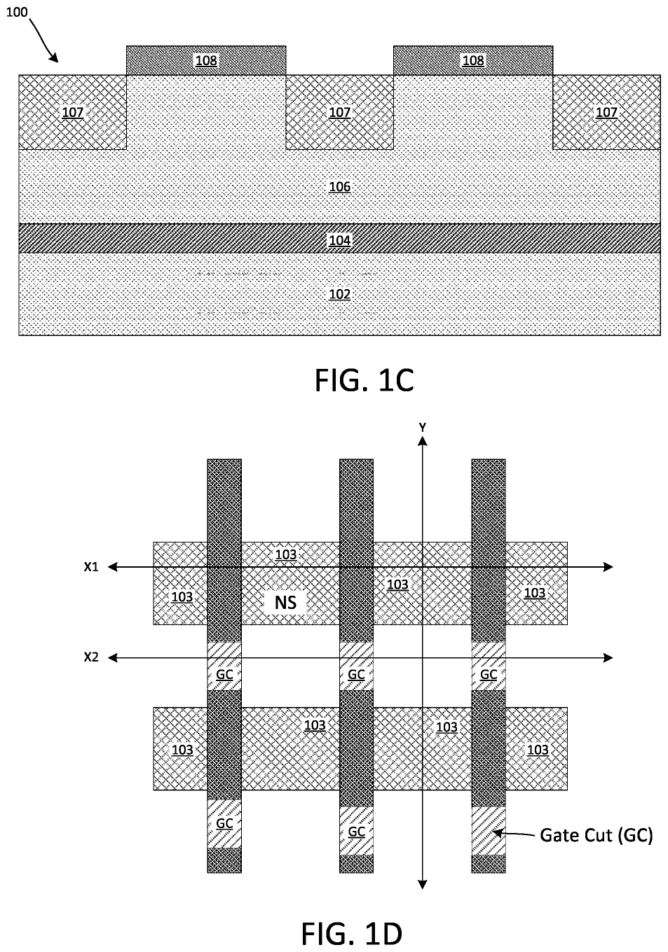

Referring now to the drawings in which like numerals represent the same or similar elements and initially to FIG. 1A, this figure depicts a cross-sectional view of the semiconductor device 100 shown in FIG. 1D taken along line X1, according to embodiments. FIG. 1D is a simplified top-down (or plan) view of the semiconductor device 100 to show the various gate lines, and the location of the active region for stacked FET. FIGS. 1A-1D illustrate the process stage after forming the etch stop layer, the active regions, the shallow trench isolation regions, the dummy gate, the gate spacer, the bottom/middle dielectric isolation layers, and the inner spacers for the stacked FET. As shown in FIG. 1A, a substrate 102 is provided. The substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate. The substrate 102 may be comprised of any other suitable material(s) than those listed above.

As shown in FIGS. 1A-1C, an etch stop layer 104 is formed on the substrate 102. The etch stop layer 104 may comprise, for example, SiO₂ or SiGe. However, it should be appreciated that the etch stop layer 104 may include other suitable materials. A second substrate 106 is formed on the etch stop layer 104. The second substrate 106 may be a bulk-semiconductor substrate similar to the substrate 102. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. The second substrate 106 may be comprised of any other suitable material(s) than those listed above. Although not shown in FIGS. 1A-1C, a bottom sacrificial layer (e.g., such as SiGe with Ge % 50˜70%, which will be converted to the bottom dielectric isolation layer 108 later) is formed on the second substrate 106.

As shown in FIGS. 1B and 1C, shallow trench isolation regions 107 are formed into the second substrate 106. In general, shallow trench isolation is an integrated circuit feature which prevents electric current leakage between adjacent semiconductor device components. STI is generally used on CMOS process technology nodes of 250 nanometers and smaller. STI regions are created early during the semiconductor device fabrication process before transistors are formed. The key steps of the STI process involve etching a pattern of trenches in the silicon, depositing one or more dielectric materials (such as silicon dioxide) to fill the trenches, and removing the excess dielectric using a technique such as chemical-mechanical planarization.

As shown in FIG. 1A, a bottom stacked FET 103 is formed on the BDI layer 108. The bottom stacked FET 103 includes a sacrificial layer 110, followed by the formation of an active semiconductor layer 112. In certain examples, the first one of the sacrificial layers 110 (i.e., the bottommost sacrificial layer) is initially formed directly on an upper surface of the BDI layer 108. In other examples, certain layers may be formed between the upper surface of the BDI layer 108 and the first one of the sacrificial layers 110. In an example, the sacrificial layer 110 is composed of silicon-germanium (e.g., SiGe35, or more generally, where the Ge ranges from about 15-35%). Next, an active semiconductor layer 112 is formed on an upper surface of the first one of the sacrificial layers 110. In an example, the active semiconductor layer 112 is composed of silicon. Several additional layers of the sacrificial layer 110 and the active semiconductor layer 108 are alternately formed. In the example illustrated in FIG. 1A, there are a total of three second type sacrificial layers 110 and two active semiconductor layers 112 that are alternately formed to form the bottom stacked FET 103. However, it should be appreciated that any suitable number of alternating layers may be formed. Although not shown in the figures, a middle isolation layer (such as SiGe with Ge % 50-70%, which will be converted to the middle dielectric isolation (MDI) layer 109 later) is formed on the bottom stacked FET 103 (or bottom nanosheet stack). Another sacrificial layer 110 (i.e., formed on the bottom stacked FET 103) may be comprised of the same or similar materials to the sacrificial layers 110 formed in the bottom stacked FET 103. In a process similar to that described above, a top stacked FET 105 (or top nanosheet stack) is formed. In the example shown in FIG. 1A, a total of two sacrificial layers 110 and two active semiconductor layers 112 are formed in the top stacked FET 105. However, it should be appreciated that the total number of alternating layers in the top stacked FET 105 may be any suitable number.

In certain embodiments, the sacrificial layers 110 have a vertical thickness ranging, for example, from approximately 3 nm to approximately 20 nm. In certain embodiments, the active semiconductor layers 112 have a vertical thickness ranging, for example, from approximately 3 nm to approximately 10 nm. Although the range of 3-20 nm is cited as an example range of thickness, other thickness of these layers may be used. In certain examples, certain of the sacrificial layers 110 and/or the active semiconductor layers 112 may have different thicknesses relative to one another. Therefore, multiple epitaxial growth processes can be performed to form the sacrificial layers 110 and the active semiconductor layers 112 shown in FIG. 1A.

In certain embodiments, it may be desirable to have a small vertical spacing (VSP) between adjacent nanosheet layers in a stack of nanosheets to reduce the parasitic capacitance and to improve circuit speed. For example, the VSP (the distance between the bottom surface of a first nanosheet layer and the top surface of an adjacent second nanosheet layer) may range from 5 nm to 15 nm. However, the VSP must be of a sufficient value to accommodate the gate stack that will be formed in the spaces created by later removal of the sacrificial layers 110.

As shown in FIGS. 1A and 1B, a dummy gate 116 (or dummy polycrystalline (PC) layer) is formed. The dummy gate 116 may be formed by any suitable deposition technique known to one of skill in the art. In one example, the dummy gate 116 is formed by depositing a thin SiO₂ dummy gate oxide layer (not shown), followed by depositing a layer of amorphous silicon (a-Si) as the dummy gate 116. The dummy gate 116 may be composed of polycrystalline silicon (poly silicon), amorphous silicon, and/or an oxide, such as, SiO₂. Gate patterning may be performed by first patterning a gate hardmask 119 and then using the patterned gate hardmask 119 to etch the dummy gates 116. After the dummy gate 116 is formed, as shown in FIG. 1A, the exposed bottom and middle sacrificial layers (e.g., SiGe with Ge % 50-70%) are selectively removed, and a spacer material is conformally deposited, forming the gate spacer 118, the BDI layer 108, and the MDI layer 109. Note that all of these different dielectric isolation layers may be deposited in a single conformal deposition step followed by an anisotropic etch process. As shown in FIG. 1C, the BDI layer 108 is formed to correspond to areas other than those occupied by the STI regions 107.

After that, the stacked nanosheets and the MDI layer 109 at the source/drain regions which are not protected by gate hardmask 119 and spacers are recessed, followed by inner spacer 114 formation. As shown in FIG. 1A, a selective etching process using, for example, a boron-based chemistry or a chlorine-based chemistry, which selectively recesses the exposed portions sacrificial layers 110 without significantly attacking the surrounding materials. Then, the inner spacers 114 are formed in the indents created by the removal of the portions of the sacrificial layers 110. An isotropic etching process may be performed to clean up the edges of the inner spacers 114.

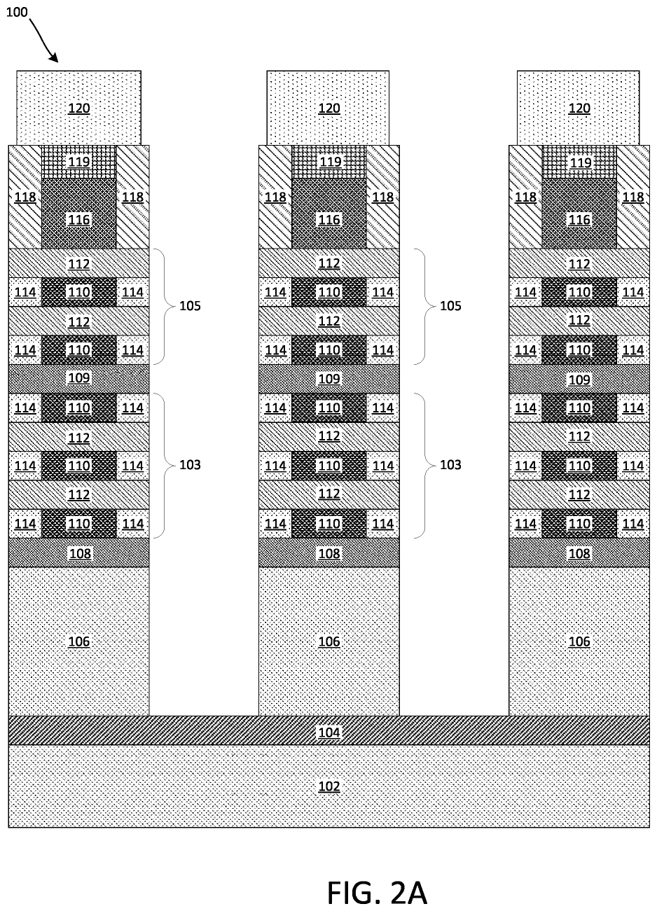

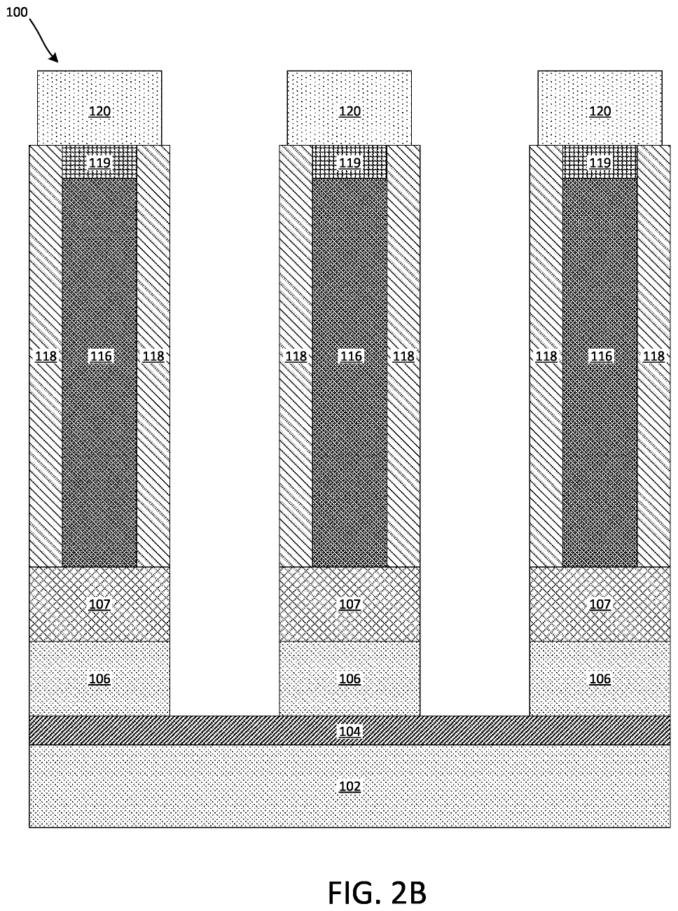

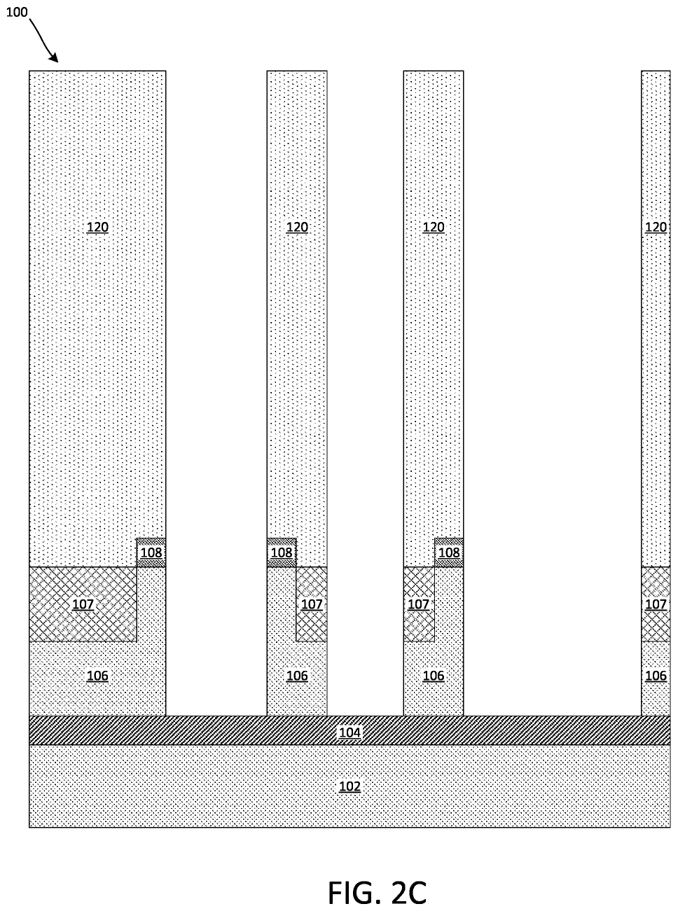

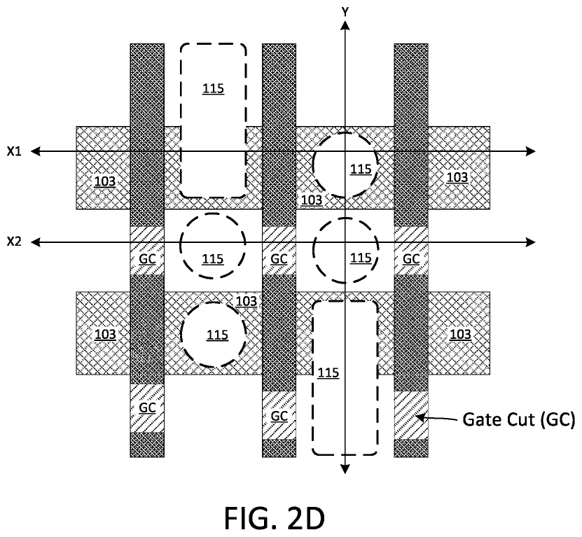

FIGS. 2A-2D illustrate a process stage after placeholder patterning for the backside contacts. Referring now to FIG. 2A, this figure is a cross-sectional view of the semiconductor device of FIG. 1A after additional fabrication operations and taken along the X1 line of FIG. 2D, according to embodiments. As shown in FIG. 2A, a self-aligned backside contact placeholder patterning is performed. In particular, a first organic planarization (OPL) layer 120 is formed. The first OPL layer 120 is patterned to have openings corresponding to backside contact locations 115 shown in FIG. 2D. Then as shown in FIGS. 2A-2C, an etching process is performed to remove the exposed portion of the STI regions 107 and the second substrate 106 down to a level of the top surface of etch stop layer 104.

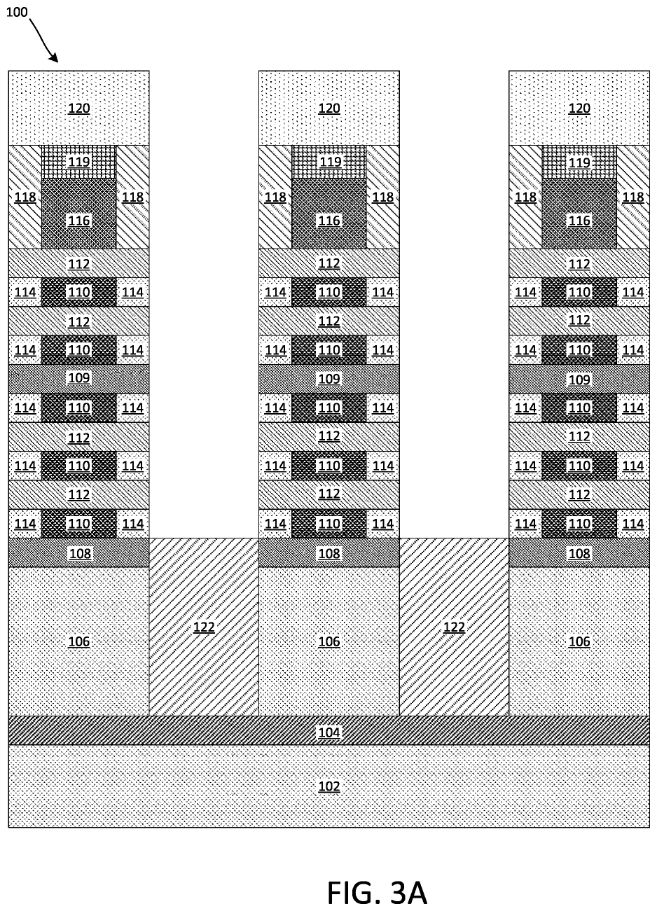

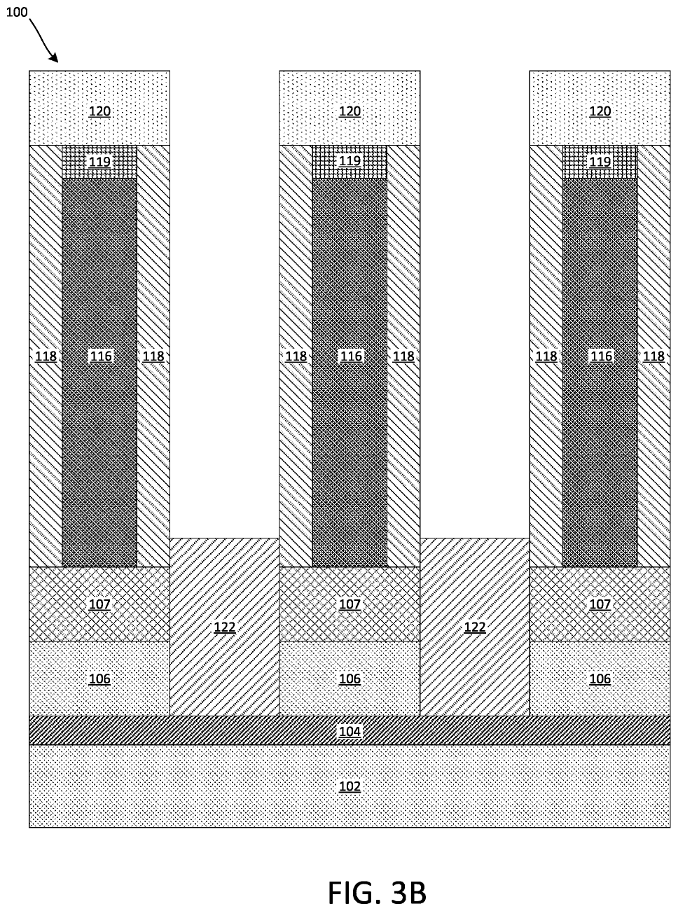

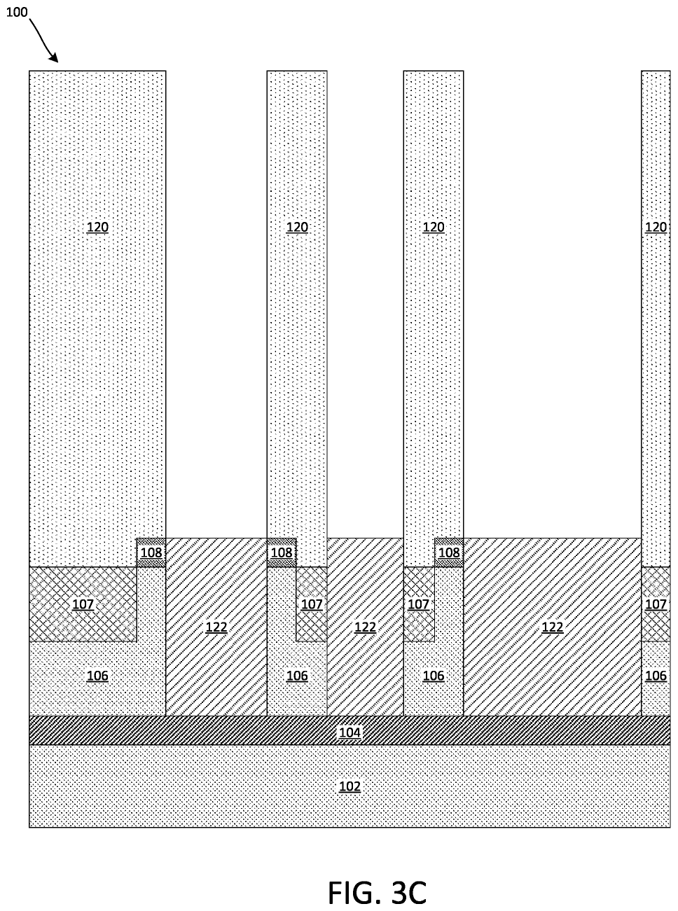

FIG. 3A-3C illustrate a process stage after sacrificial placeholder formation for backside contact. Referring now to FIG. 3A, this figure is a cross-sectional view of the semiconductor device of FIG. 2A after additional fabrication operations and taken along the X1 line of FIG. 2D, according to embodiments. As shown in FIGS. 3A-3C, after the backside contact placeholder openings have been formed, a self-aligned backside contact placeholder layer 122 (or backside contact placeholder) is formed. In one example, the backside contact placeholder layer 122 is formed up to a level at or about a top surface of the BDI layer 108. In certain examples, the backside contact placeholder layer 122 comprises one or more sacrificial materials, such as TiOₓ, AlOₓ, SiC, etc.

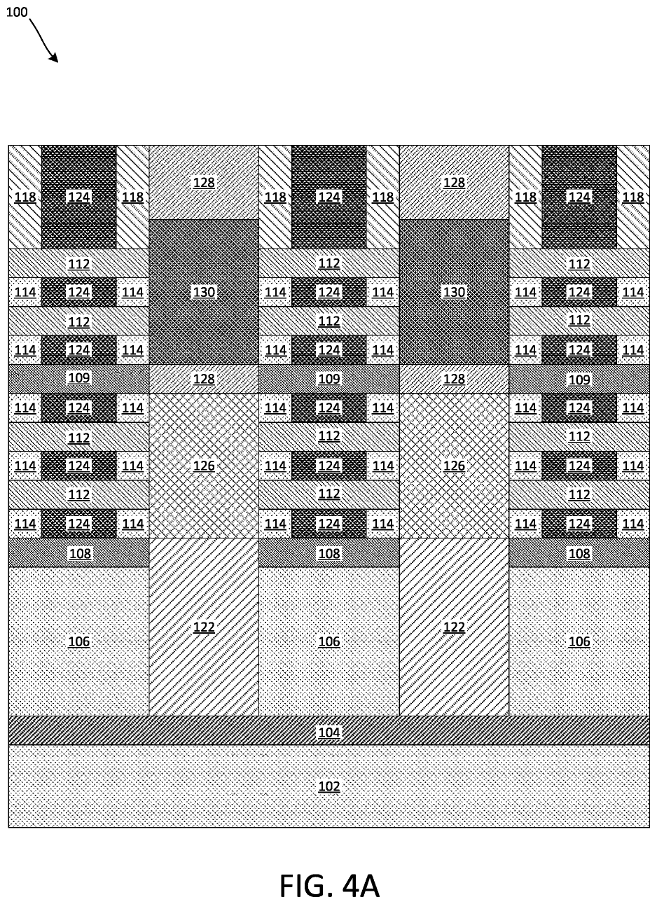

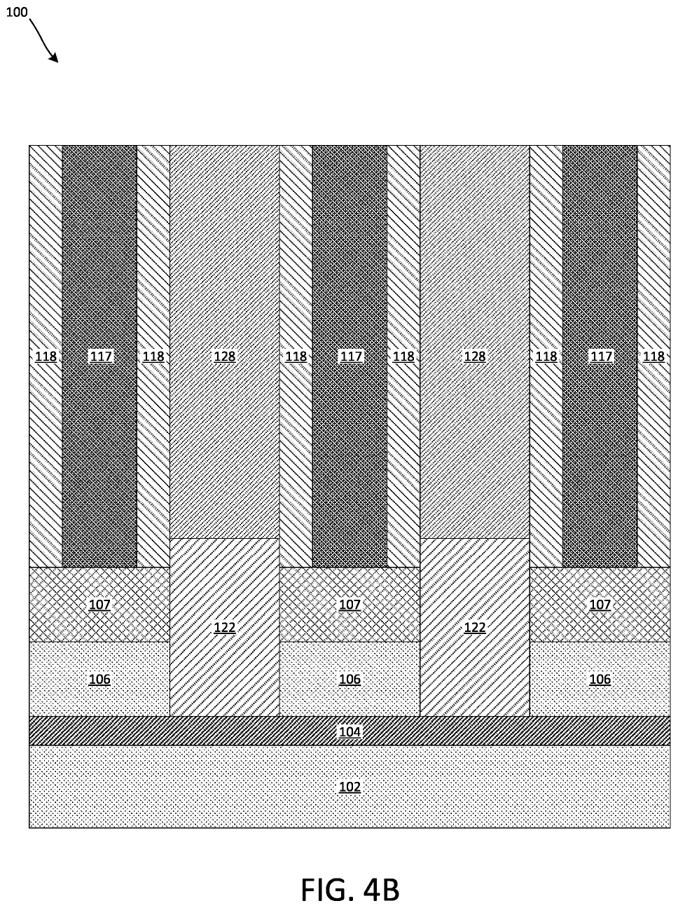

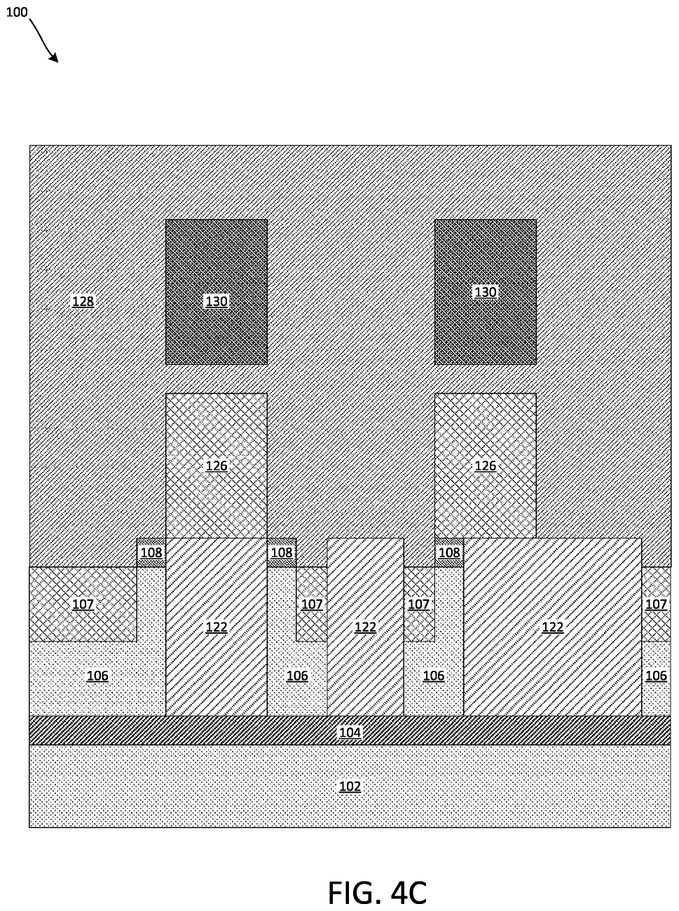

FIG. 4A-4C illustrate a process stage after the formation of the bottom source/drain (S/D) epitaxial layer 126, the top S/D epitaxial layer 130, the bottom interlayer dielectric (ILD) layer 128, the gate cut, and the formation of the replacement gate (or HKMG 124). Referring now to FIG. 4A, this figure is a cross-sectional view of the semiconductor device of FIG. 3A after additional fabrication operations and taken along the X1 line of FIG. 2D, according to embodiments. As shown in FIGS. 4A and 4B, after the backside contact placeholder layer 112 is formed, a bottom S/D epitaxial layer 126 (or bottom epitaxial layer) is formed, followed by formation of the bottom ILD layer 128, and then top S/D epitaxial layer 130 (or top epitaxial layer) formation. After the formation of the top S/D epitaxial layer 130, additional ILD material is deposited above and around the top S/D epitaxial layer 130 to add to the bottom ILD layer 128. As shown in FIG. 4B, the additional ILD material is also formed between dummy gate 116. As shown in FIG. 4C, the additional ILD material is also formed between the bottom S/D epitaxial layer 126 and top S/D epitaxial layer 130. In certain examples, after the continued formation of the bottom ILD layer 128, a material removal process such as CMP may be performed to planarize the top surface of the semiconductor device 100 and to remove any excess material. Then, a gate cut patterning process is performed to etch away the dummy gate in gate cut region, (see FIG. 1D for the locations of the gate cuts), followed by filling the gate cut region with dielectric material 117. Then, dummy gate 116 is selectively removed, followed by removal of (or release) the SiGe material of the sacrificial layers 110. After the material of the sacrificial layers 110 has been released, a high-K metal gate (HKMG) 124 is formed in the spaces created by the removal of the SiGe material of the sacrificial layers 110. In certain examples, after the formation of the HKMG 124, a material removal process such as CMP may be performed to planarize the top surface of the semiconductor device 100 and to remove any excess material or overburden.

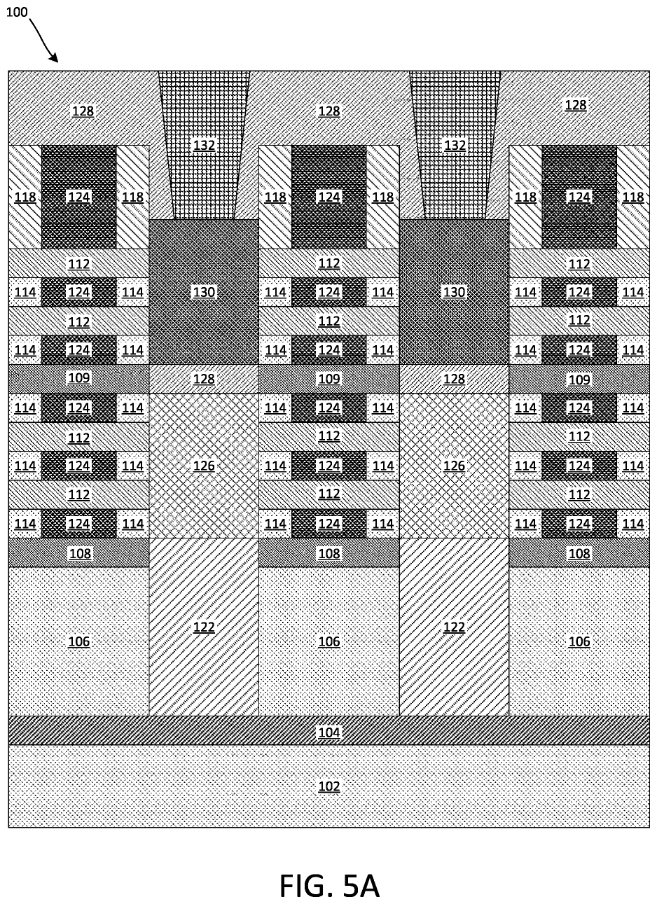

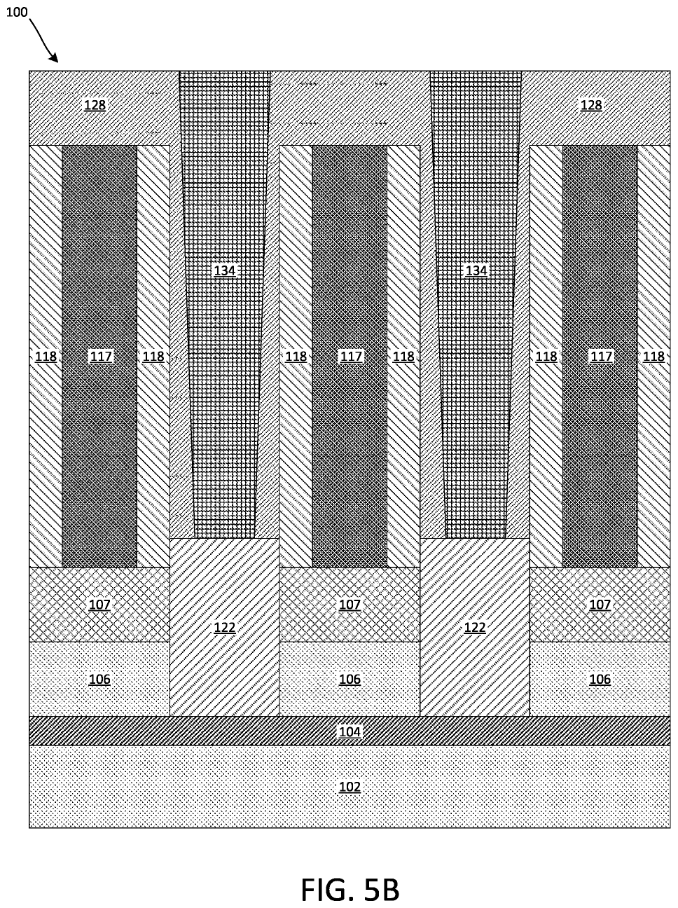

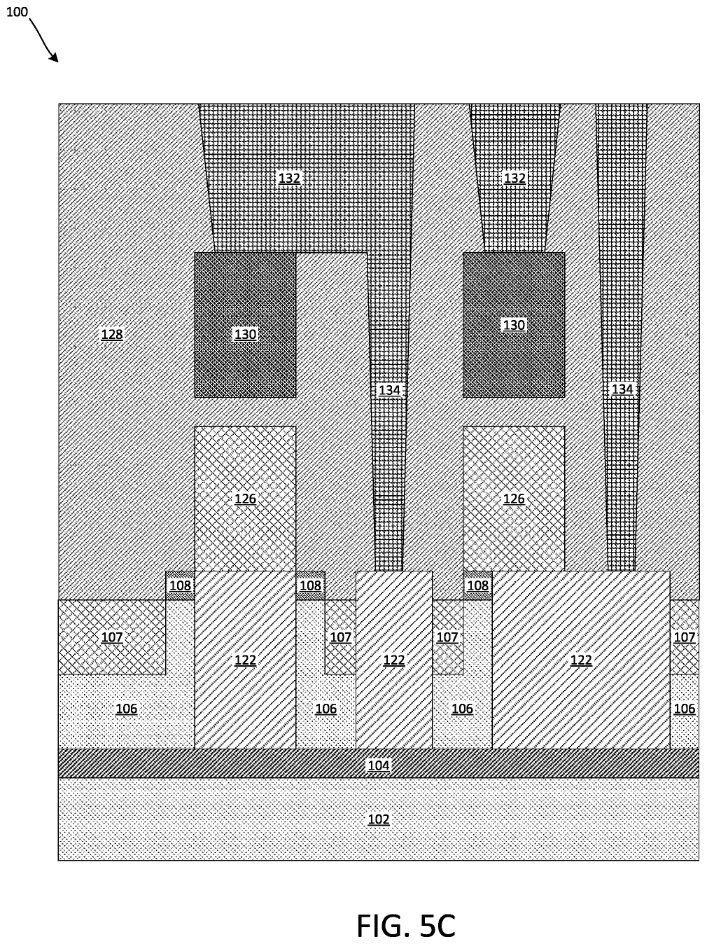

FIG. 5A-5C illustrate a process stage after formation of middle of line contacts. Referring now to FIG. 5A, this figure is a cross-sectional view of the semiconductor device of FIG. 4A after additional fabrication operations and taken along the X1 line of FIG. 2D, according to embodiments. As shown in FIGS. 5A-5C, additional ILD material is deposited above the HKMG 124 to continue the formation of the bottom ILD layer 128 (i.e., this material may also be referred to as a middle of the line (MOL) ILD layer). A patterning layer (not shown) such as an organic planarization layer (OPL) may be formed to create a mask for forming the various contact vias. Then first metal contacts 132 (or source/drain (S/D) contacts) and vias to backside power rails (VBPRs) 134 (or a metal contact via connected to a backside power rail) are formed. As shown in FIGS. 5A and 5C, the first metal contacts 132 are formed to a sufficient depth to contact the top S/D epitaxial layer 130. As shown in FIGS. 5B and 5C, the VBPRs 134 are formed deeper to contact the backside contact placeholder layer 122. As shown in FIG. 5C, the leftmost VBPR 134 is in direct contact with the leftmost first metal contact 132.

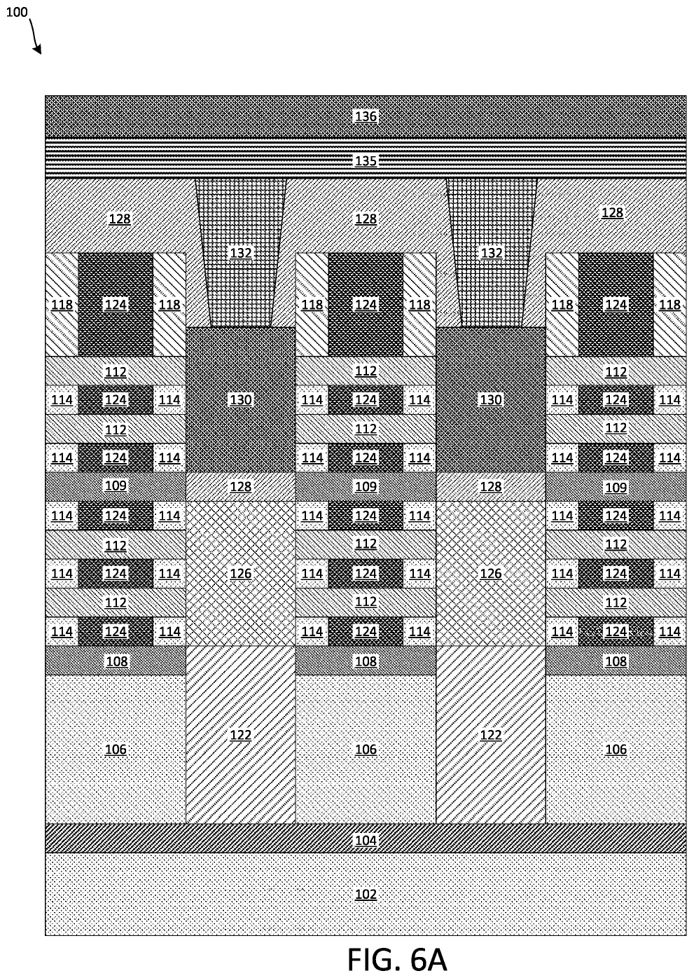

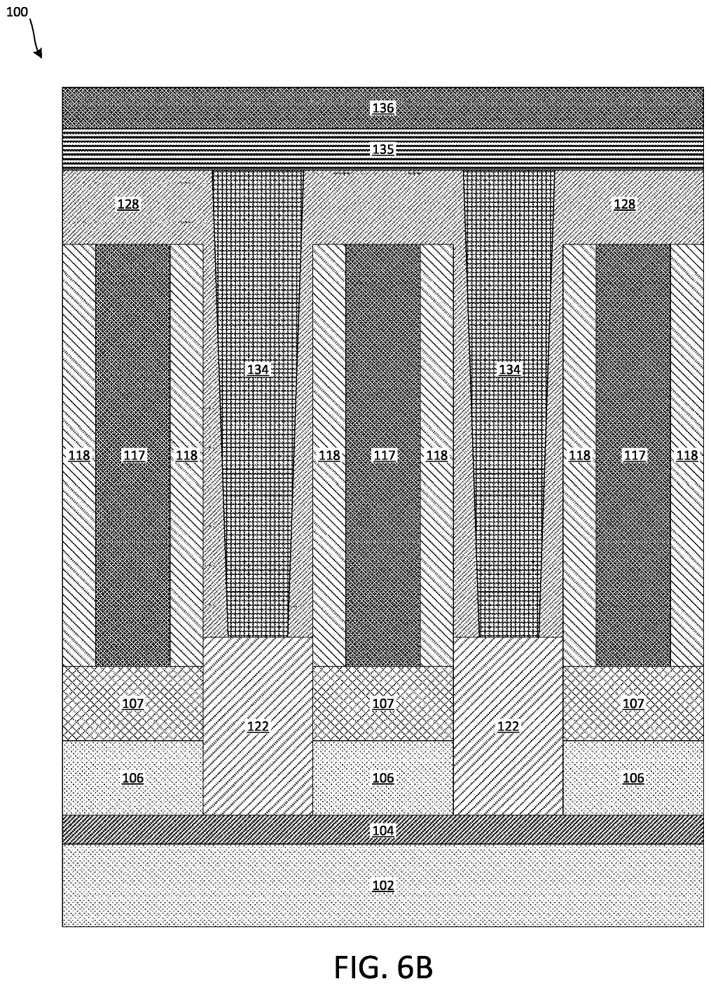

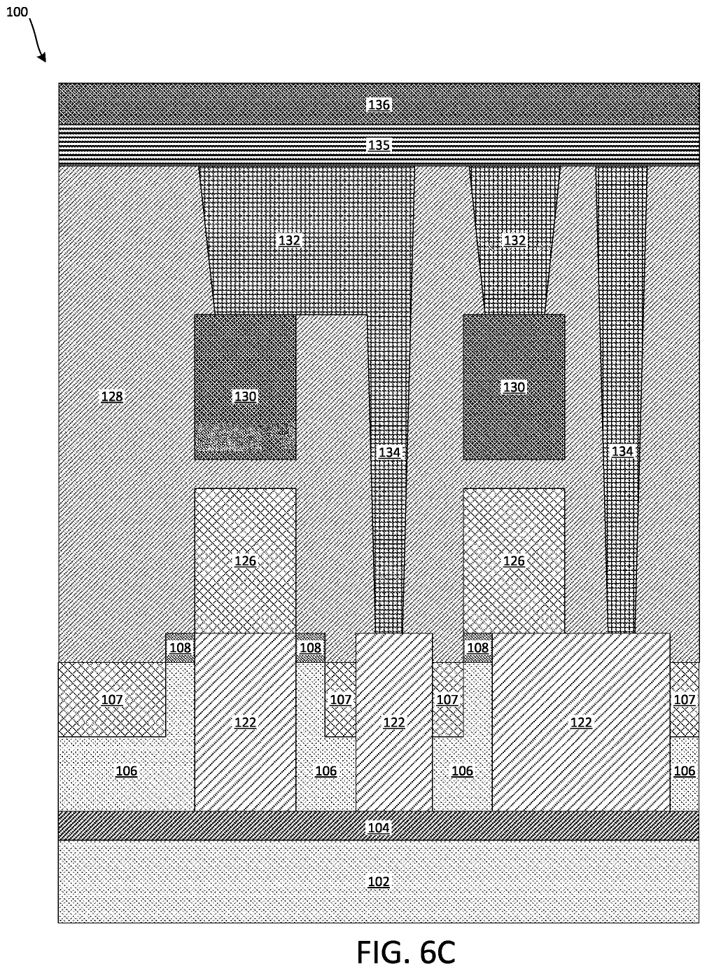

FIGS. 6A-6C illustrate a process stage after formation of the back-end-of-line (BEOL) interconnect 135 and bonding a carrier wafer 136. Referring now to FIG. 6A, this figure depicts a cross-sectional view of the semiconductor device 100 shown in FIG. 5A after additional manufacturing operations and taken along line X1 of FIG. 2D, according to embodiments. As shown in FIGS. 6A-6C, a back end of line (BEOL) interconnect 135 is formed on the top surface of the first contacts CA 132 and the VBPRs 134. In general, the BEOL is the second portion of IC fabrication where the individual devices (transistors, capacitors, resistors, etc.) get interconnected with wiring on the wafer and the metallization layer. BEOL generally begins when the first layer of metal is deposited on the wafer. BEOL includes contacts, insulating layers (dielectrics), metal levels, and bonding sites for chip-to-package connections. Then, a carrier wafer 136 is provided on the BEOL interconnect 135.

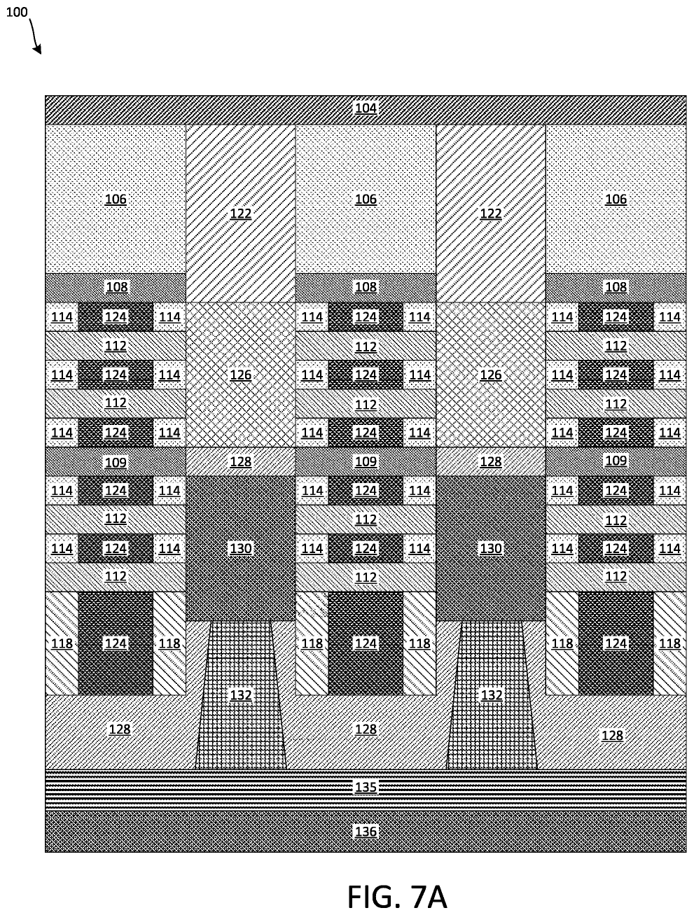

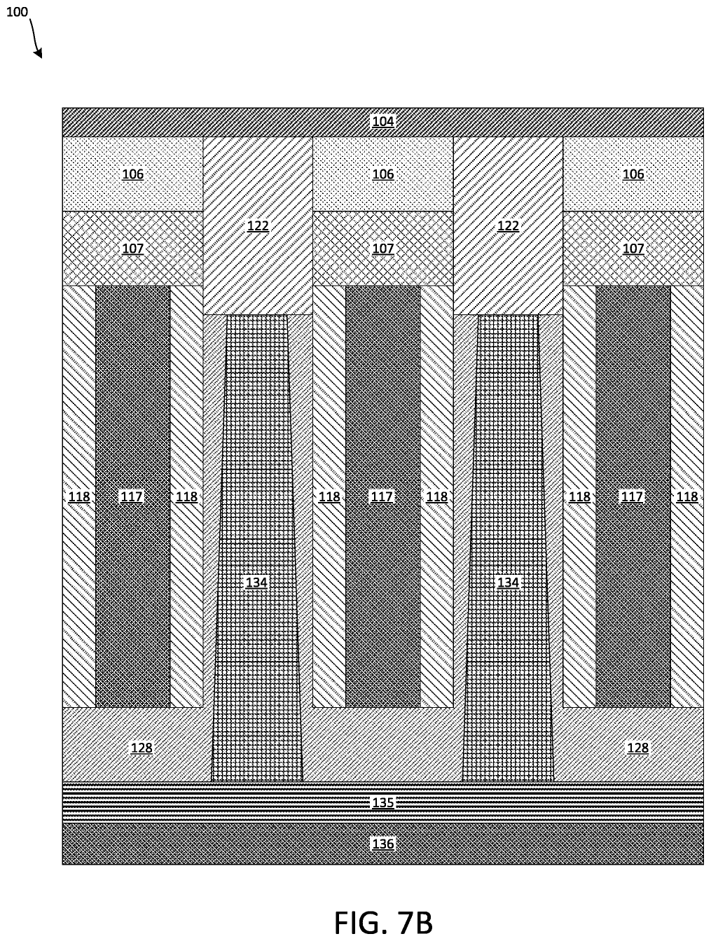

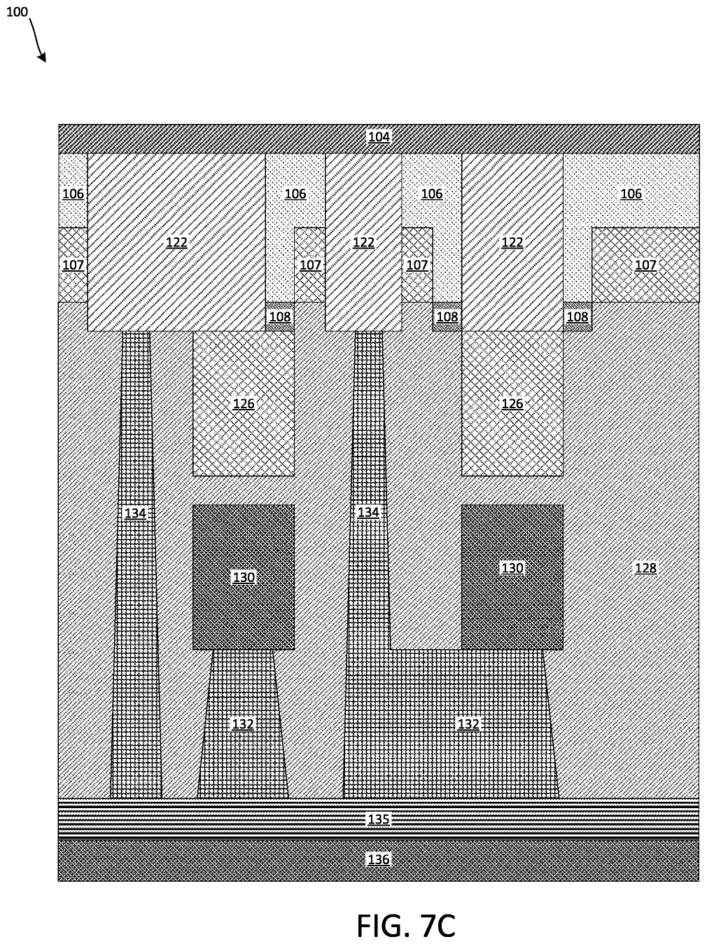

FIGS. 7A-7C illustrate a process stage after wafer flip and the removal of substrate 102, stopping on etch stop layer 104. Referring now to FIG. 7A, this figure depicts a cross-sectional view of the semiconductor device 100 shown in FIG. 6A after additional manufacturing operations and taken along line X1 of FIG. 2D, according to embodiments. As shown in FIGS. 7A-7C, the semiconductor device 100 is flipped upside down and the substrate 102 is removed, exposing the etch stop layer 104.

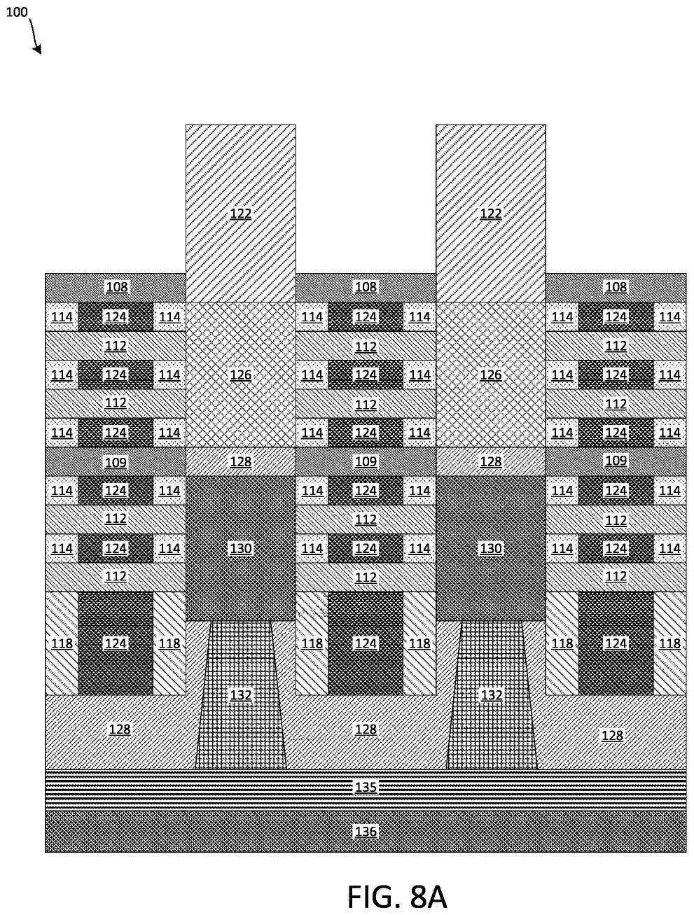

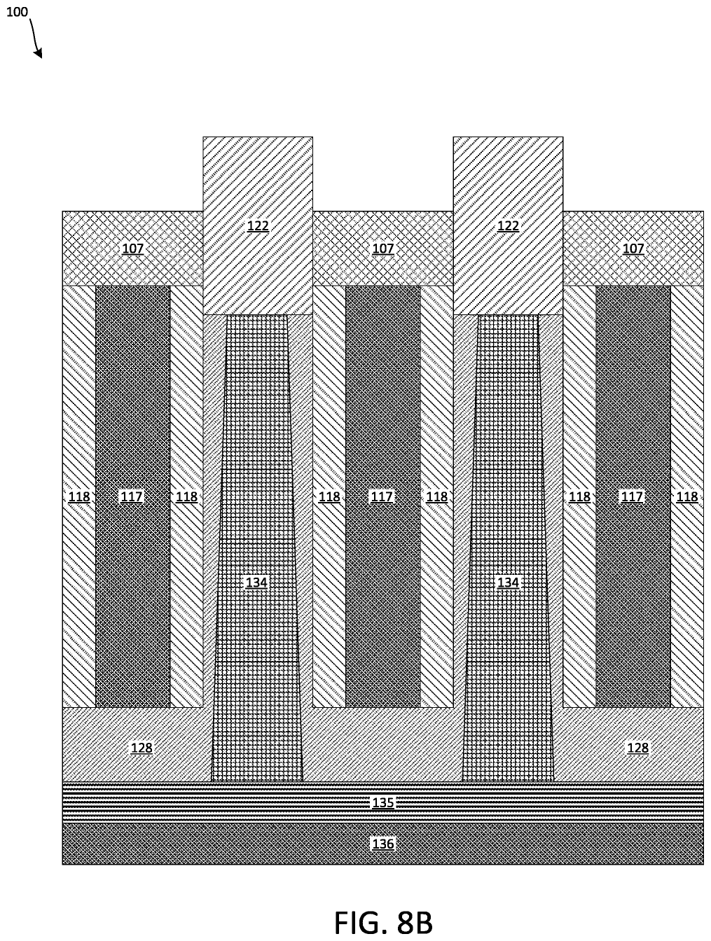

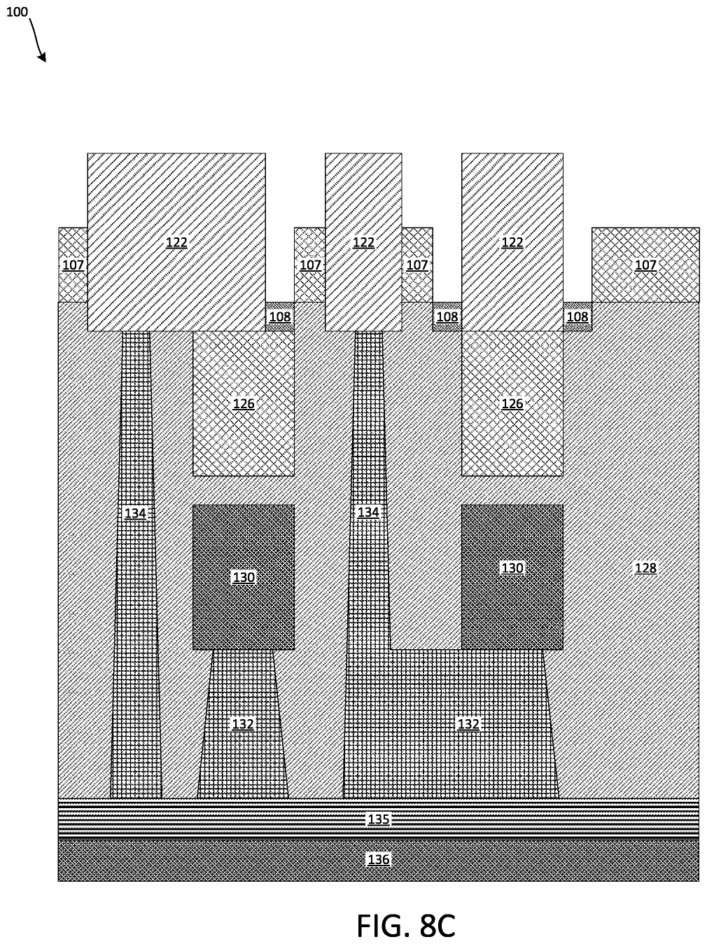

FIGS. 8A-8C illustrate a process stage after removing the etch stop layer 104 and second substrate 106 (or semiconductor layer). Referring now to FIG. 8A, this figure depicts a cross-sectional view of the semiconductor device 100 shown in FIG. 7A after additional manufacturing operations and taken along line X1 of FIG. 2D, according to embodiments. As shown in FIGS. 8A-8C, the etch stop layer 104 is removed with any suitable material removal process. Then, the remaining Si material of the second substrate 106 is also removed. As shown in FIG. 8A, this exposes the BDI layer 108. As also shown in FIG. 8B, this exposes the STI regions 107.

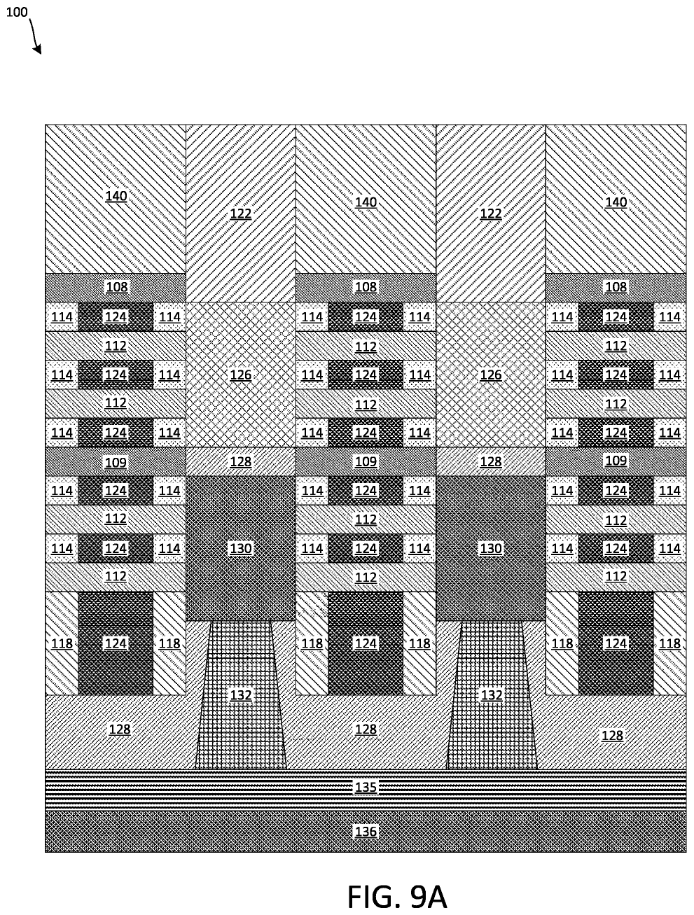

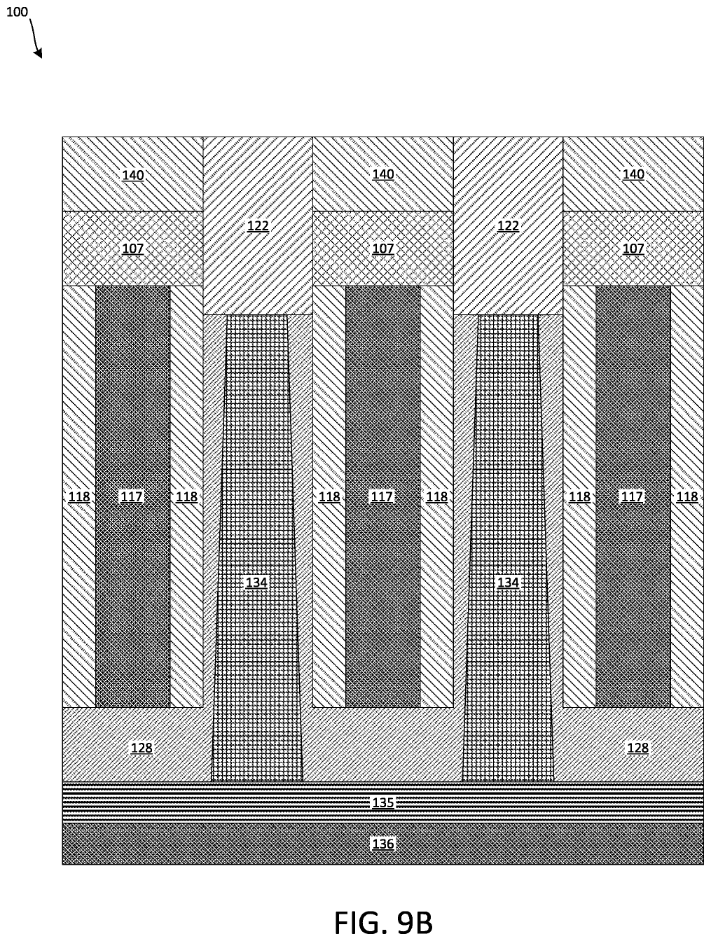

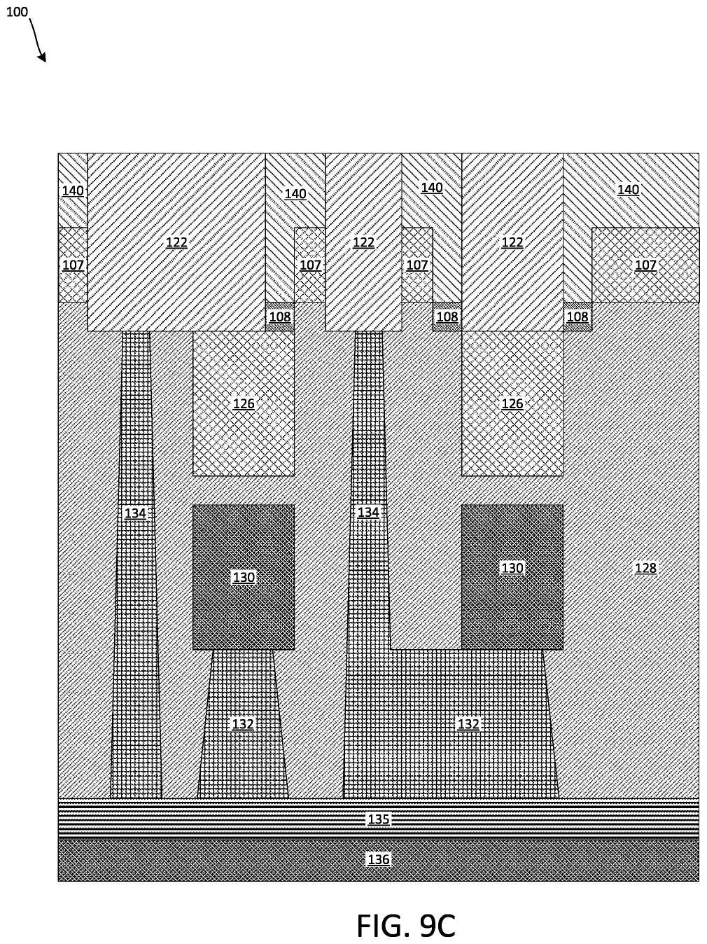

FIGS. 9A-9C illustrate a process stage after the formation of the backside ILD layer 140, and the backside ILD CMP process, stopping on the sacrificial backside contact placeholder layer 122. Referring now to FIG. 9A, this figure depicts a cross-sectional view of the semiconductor device 100 shown in FIG. 8A after additional manufacturing operations and taken along line X1 of FIG. 2D, according to embodiments. As shown in FIGS. 9A-9C, after the removal of the etch stop layer 104 and the second substrate 106, a backside ILD layer 140 is formed to fill in the spaces where the material of the etch stop layer 104 and the second substrate 106 was removed. It should be appreciated that the material of the backside ILD layer may include one or more suitable dielectric materials and may be the same material or different than the material of the bottom ILD layer 128. In certain examples, a material removal process such as CMP may then be performed to planarize the surface of the semiconductor device 100 and remove any overburden of the backside ILD layer 140.

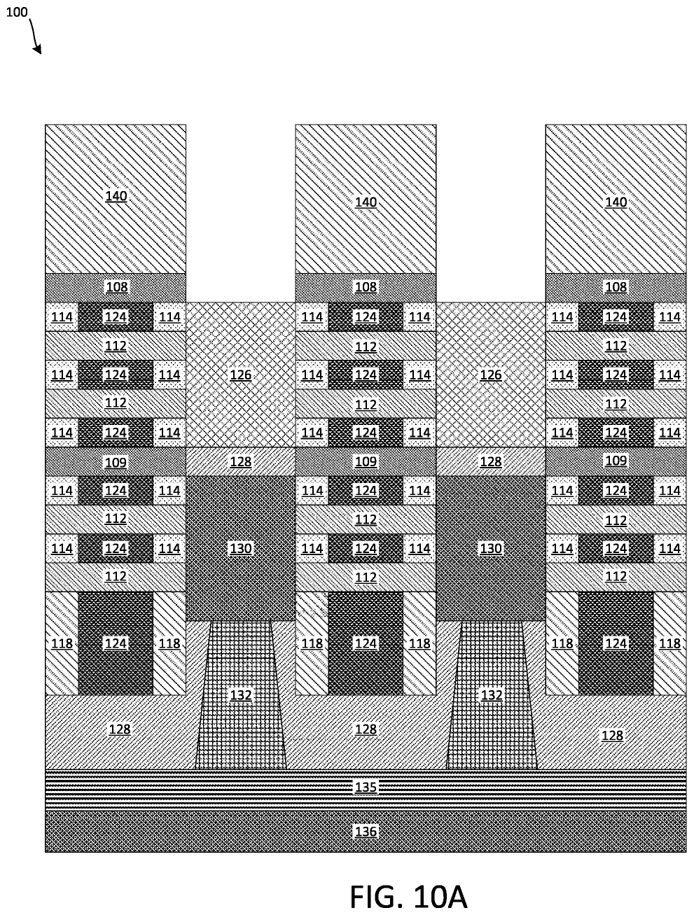

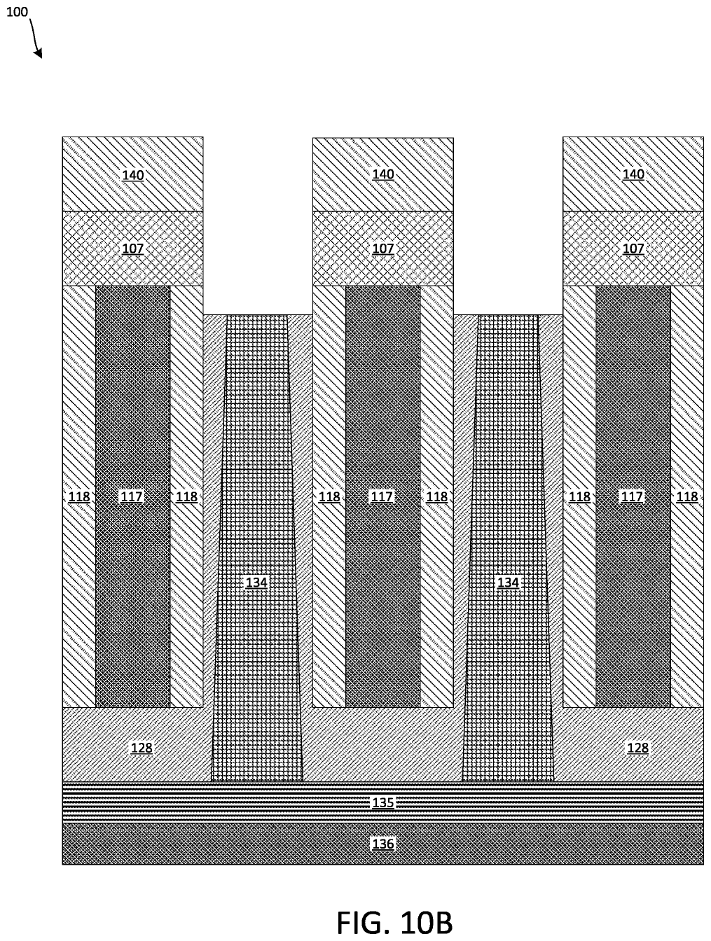

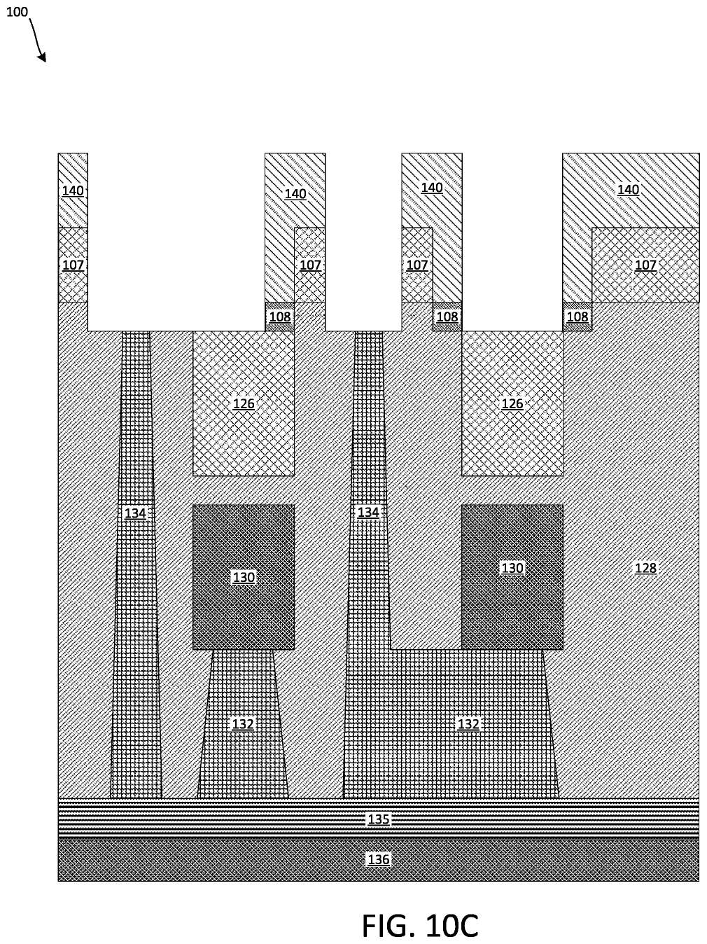

FIGS. 10A-10C illustrate a process stage after the selective removal of the sacrificial backside contact placeholder layer 122 material. Referring now to FIG. 10A, this figure depicts a cross-sectional view of the semiconductor device 100 shown in FIG. 9A after additional manufacturing operations and taken along line X1 of FIG. 2D, according to embodiments. As shown in FIGS. 10A-10C, the backside contact placeholder layer 122 is removed in a self-aligned manner. Thus, as shown in FIGS. 10A and 10C, the bottom S/D epitaxial layer 126 is exposed. Also, as shown in FIGS. 10B and 10C, the VBPRs 134 are also exposed.

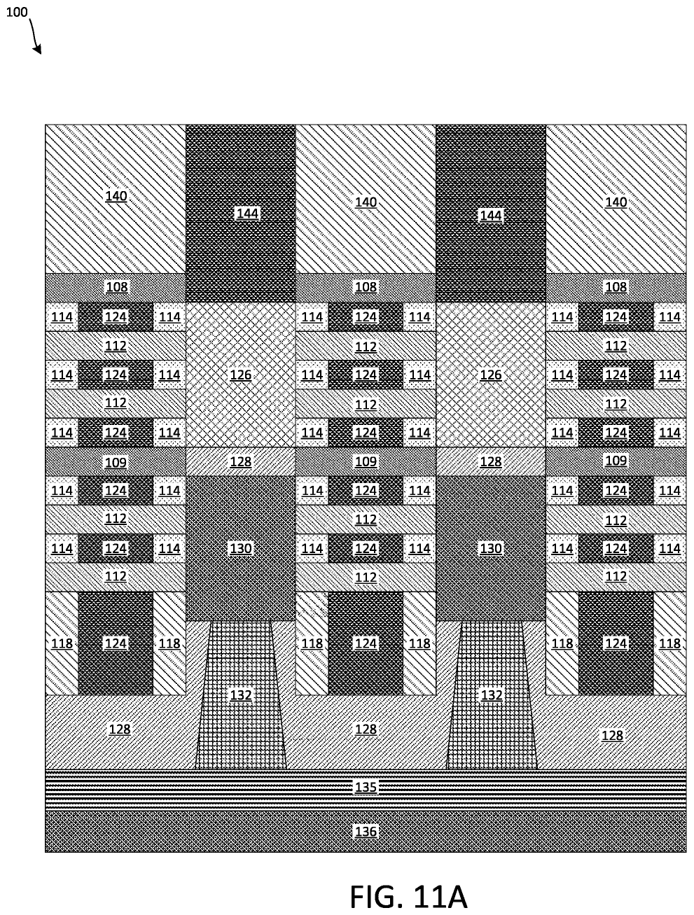

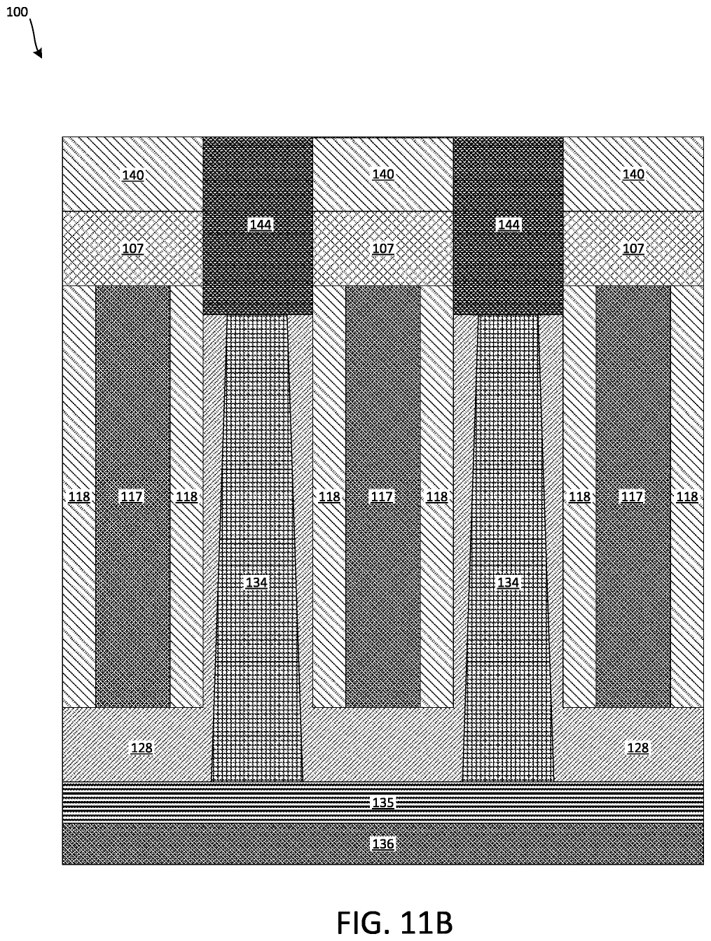

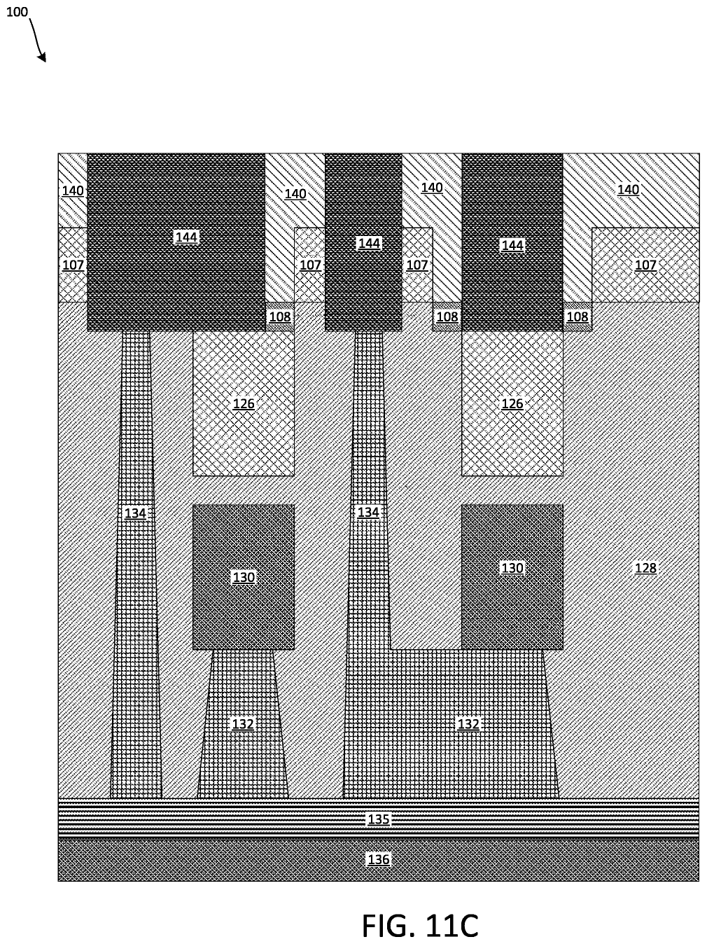

FIGS. 11A-11C illustrate a process stage after formation of backside contact metallizations 144. Referring now to FIG. 11A, this figure depicts a cross-sectional view of the semiconductor device 100 shown in FIG. 10A after additional manufacturing operations and taken along line X1 of FIG. 2D, according to embodiments. As shown in FIGS. 11A-11C, backside contact metallizations (BSCA) 144 are formed in each of the areas where the backside contact placeholder layer 122 was removed as described above with respect to FIGS. 10A-10C. As shown in FIG. 11C, the leftmost BSCA 144 contacts both the leftmost VBPR 134 and the leftmost bottom S/D epitaxial layer 126.

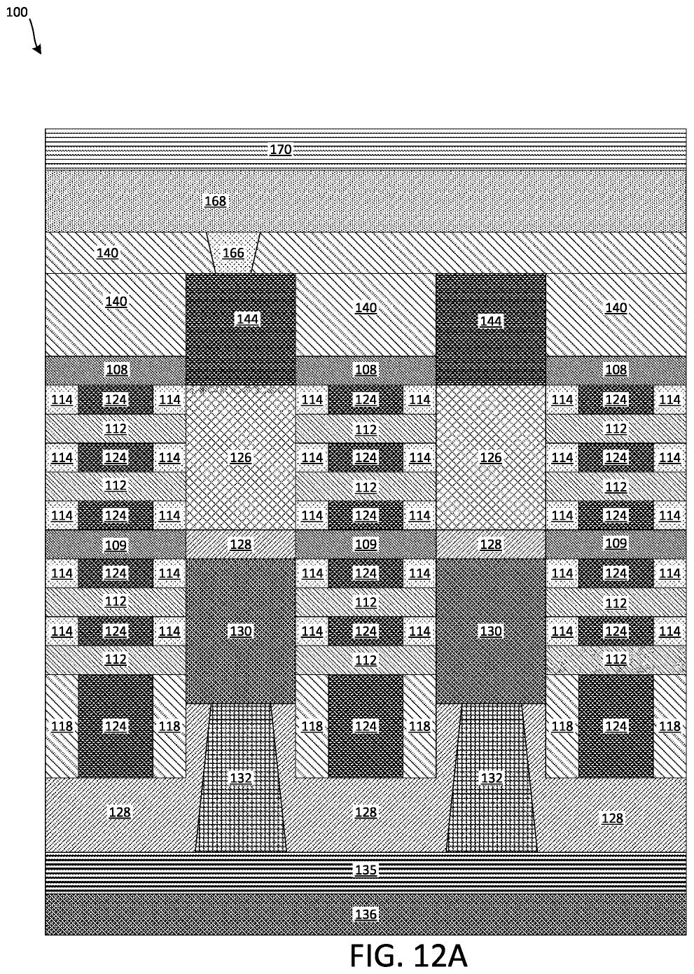

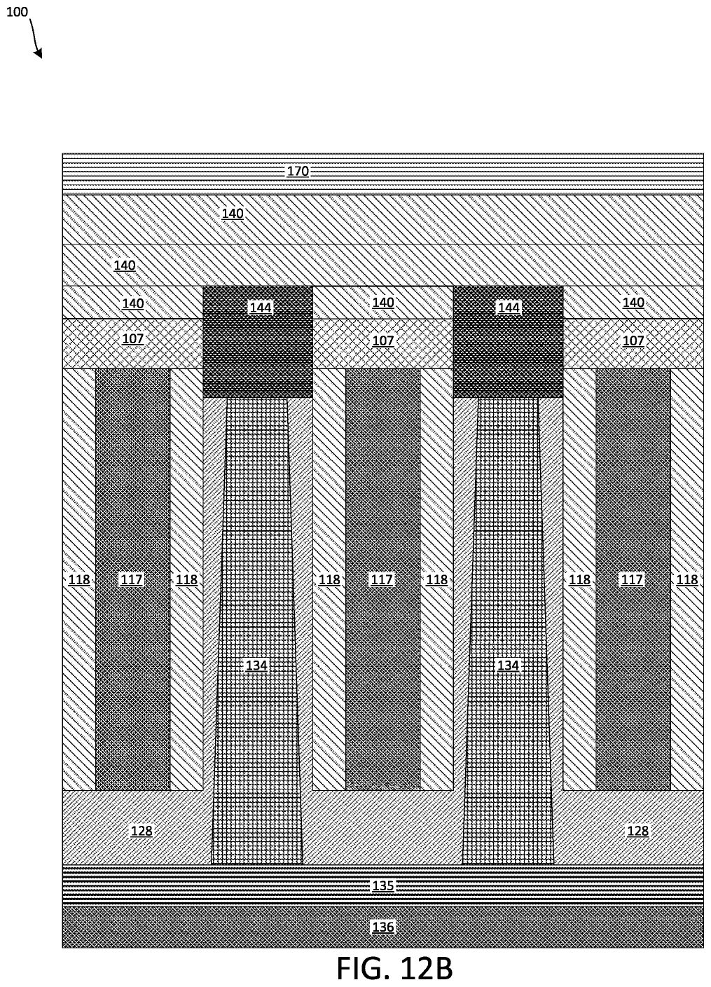

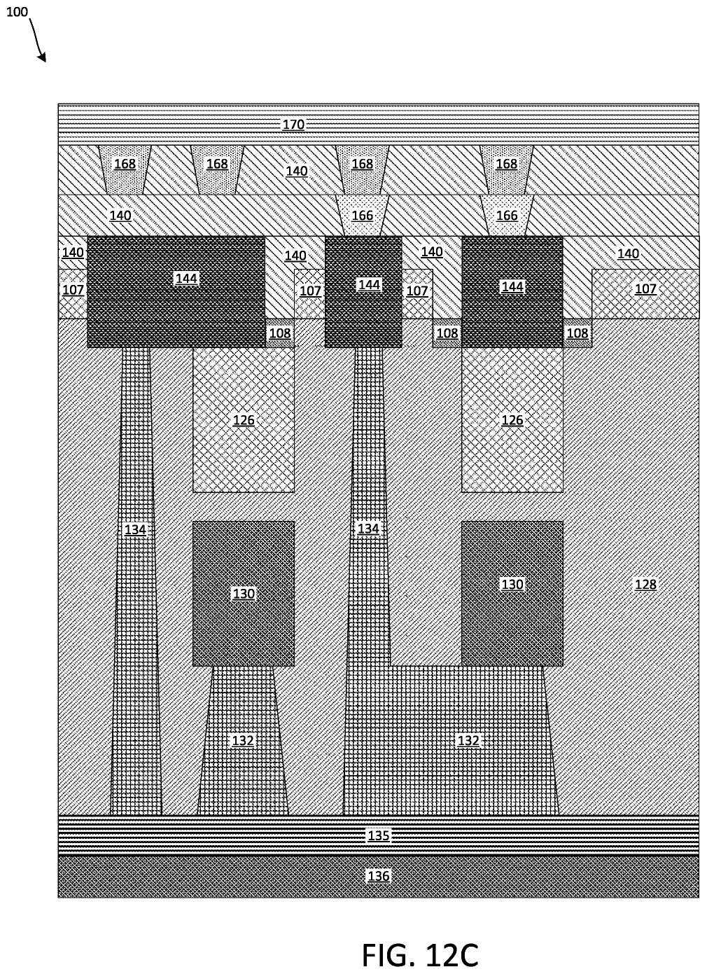

FIGS. 12A-12C illustrate a process stage after formation of additional backside interconnects. Referring now to FIG. 12A, this figure depicts a cross-sectional view of the semiconductor device 100 shown in FIG. 11A after additional manufacturing operations and taken along line X1 of FIG. 2D, according to embodiments. As shown in FIGS. 12A-12C, additional ILD material is deposited over the BSCAs 144, which may be considered as an extension of the backside ILD layer 140. Then, as shown in FIGS. 12A and 12C, metallic backside vias 166 (or backside vias) are formed into the backside ILD layer 140 to contact certain of the BSCAs 144. Also, as shown in FIGS. 12A and 12C, a backside power rail (BSPR) 168 is formed through the backside ILD layer 140 to contact certain of the backside vias 166. As shown in FIG. 12C, the rightmost VBPR 134 connects to the middle BSCA 144, the middle BSCA 144 connects to the BSPR 168, the same rightmost VBPR 134 connects to the BEOL interconnect 135, and the same rightmost VBPR 134 connects to the rightmost first metal contact 132 which is connected to the rightmost top S/D epitaxial layer 130.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first field effect transistor (FET);
a second FET stacked over the first FET;
a backside contact (BSCA) connected to a backside power rail (BSPR); and
a via to backside power rail (VBPR), the VBPR positioned over the BSCA.

2. The semiconductor device of claim 1, wherein the first FET and the second FET include alternating layers of active semiconductor layers and high-K metal gate layers.

3. The semiconductor device according to claim 2, further comprising a gate spacer surrounding the high-K metal gate layers.

4. The semiconductor device according to claim 1, further comprising a bottom epitaxial layer and a top epitaxial layer.

5. The semiconductor device of claim 4, wherein the BSCA contacts the bottom epitaxial layer.

6. The semiconductor device of claim 4, wherein the BSCA connects to the BSPR through a backside via.

7. The semiconductor device according to claim 1, further comprising a back end of line (BEOL) structure.

8. The semiconductor device according to claim 7, wherein the VBPR connects to the BEOL structure.

9. The semiconductor device according to claim 4, further comprising a S/D contact in contact with the top epitaxial layer.

10. The semiconductor device according to claim 9, wherein the VBPR is formed in contact with the S/D contact.

11. A method of manufacturing a semiconductor device, the method comprising:
forming a first field effect transistor (FET);
forming a second FET that is stacked over the first FET;
forming a backside contact (BSCA) that is connected to a backside power rail (BSPR); and
forming a via to backside power rail (VBPR), the VBPR positioned over the BSCA.

12. The method of claim 11, wherein the first FET and the second FET include alternating layers of active semiconductor layers and high-K metal gate layers.

13. The method according to claim 12, further comprising forming a gate spacer surrounding the high-K metal gate layers.

14. The method according to claim 11, further comprising:
forming a bottom epitaxial layer and a top epitaxial layer;
forming a backside contact placeholder that is under the bottom epitaxial layer;
removing the backside contact placeholder; and
forming the BSCA in an area where the backside contact placeholder was removed.

15. The method of claim 14, wherein the BSCA contacts the bottom epitaxial layer.

16. The method of claim 14, wherein the BSCA connects to the BSPR through a backside via.

17. The semiconductor device according to claim 11, further comprising forming a back end of line (BEOL) structure.

18. The method according to claim 17, wherein the VBPR connects to the BEOL structure.

19. The method according to claim 14, further comprising forming a S/D contact in contact with the top epitaxial layer.

20. The method according to claim 19, wherein the VBPR is formed in contact with the S/D contact.
